(19) United States
(12) Patent Application Publication
(10) Pub. No.: US 2026/0190244 A1
(43) Pub. Date: Jul. 2, 2026

(54) METHOD AND ARRANGEMENT FOR FORMING A PERMANENT CONNECTION BETWEEN TWO CONNECTION PARTNERS

(71) Applicant: Infineon Technologies AG, Neubiberg (DE)

(72) Inventors: Arthur Unrau, Geseke (DE); Johann Gatterbauer, Parsberg (DE); Florian Berger, Bad Abbach (DE)

(21) Appl. No.: 19/427,012

(22) Filed: Dec. 19, 2025

(30) Foreign Application Priority Data
Jan. 2, 2025 (DE) 102025100009.3

(51) Int. Cl. H05K 3/00; H10W 40/00

(52) U.S. Cl. CPC H05K 3/0061; H10W 40/037; H05K 2203/01; H05K 2203/1131

(57) ABSTRACT

A method includes: applying a pre-layer to a first or second connection partner; arranging the first connection partner on the second connection partner with the pre-layer arranged therebetween; heating the connection partners with the pre-layer arranged therebetween; and while heating, exerting pressure on the first connection partner such that the first connection partner is pressed towards the second connection partner and a permanent connection layer is formed between the connection partners. A first pressure exerted on at least one first section of the first connection partner is less than a second pressure exerted on at least one second section of the first connection partner. The resulting permanent connection layer has a higher porosity in areas arranged below the at least one first section of the first connection partner and a lower porosity in areas arranged below the at least one second section of the first connection partner.

### TECHNICAL FIELD

The instant disclosure relates to a method and an arrangement for forming a permanent connection between two connection partners, in particular for forming a sintered layer between two connection partners.

### BACKGROUND

Semiconductor module arrangements often include at least one substrate. A semiconductor arrangement including a plurality of controllable semiconductor elements (e.g., two or more IGBTs) is arranged on each of the at least one substrate. Each substrate usually comprises a substrate layer (e.g., a ceramic layer), a first metallization layer deposited on a first side of the substrate layer and a second metallization layer deposited on a second side of the substrate layer. The controllable semiconductor elements are mounted, for example, on the first metallization layer. At least some controllable semiconductor elements of the semiconductor module arrangement perform a plurality of switching operations during the operation of the semiconductor module arrangement. When performing many switching operations within a short period of time, for example, the controllable semiconductor elements generate heat. Heat that is generated during the operation of the semiconductor module arrangement is mostly dissipated from the controllable semiconductor elements to the substrate and further to a heat sink. The substrate usually is sintered to a respective heat sink by means of a sintered layer. The sintered layer deforms when heated. Usually, some sections of the substrate are heated more than others during operation of the semiconductor module. Therefore, the sintered layer may also heat unevenly. Over the lifetime of a semiconductor module, a great number of heating and cooling cycles are performed. This may drastically reduce the lifetime of the semiconductor module, because the sintered layer between the substrate and the heat sink may be corrupted over time and the function of the semiconductor module may not be guaranteed anymore.

There is a need for a method and an arrangement for forming a stable and reliable permanent connection between a first and a second connection partner.

### SUMMARY

A method includes applying a pre-layer to a first connection partner or to a second connection partner, arranging the first connection partner on the second connection partner, such that the pre-layer is arranged between the first connection partner and the second connection partner, heating the first connection partner, the second connection partner, and the pre-layer arranged between the first connection partner and the second connection partner, and while heating the first connection partner, the second connection partner, and the pre-layer, exerting pressure on the first connection partner, thereby pressing the first connection partner towards the second connection partner and forming a permanent connection layer between the first connection partner and the second connection partner, wherein exerting pressure on the first connection partner includes exerting a first pressure on at least one first section of the first connection partner, and exerting a second pressure on at least one second section of the first connection partner, wherein the second pressure is greater than the first pressure, and the resulting permanent connection layer in areas arranged below the at least one first section of the first connection partner has a first porosity, and in areas arranged below the at least one second section of the first connection partner has a second porosity, wherein the second porosity is lower than the first porosity.

An arrangement for forming a permanent connection between two connection partners includes a pressing tool, the pressing tool including an upper punch, and a plurality of pressure transmission elements attached to the upper punch, the plurality of pressure transmission elements including at least one pressure transmission element of a first kind and at least one pressure transmission element of a second kind, wherein the upper punch is configured to exert pressure on a first connection partner, with the plurality of pressure transmission elements arranged between the upper punch and the first connection partner, thereby pressing the first connection partner on a second connection partner, with a pre-layer arranged between the first connection partner and the second connection partner, and each pressure transmission element of the first kind is configured to transmit a first pressure from the upper punch to one of at least one first section of the first connection partner, and each pressure transmission element of the second kind is configured to transmit a second pressure from the upper punch to one of at least one second section of the first connection partner, wherein the second pressure is greater than the first pressure.

The invention may be better understood with reference to the following drawings and the description. The components in the figures are not necessarily to scale, emphasis instead being placed upon illustrating the principles of the invention. Moreover, in the figures, like referenced numerals designate corresponding parts throughout the different views.

### BRIEF DESCRIPTION OF THE DRAWINGS

FIG. 1 is a cross-sectional view of a semiconductor module arrangement.

FIG. 2 is a cross-sectional view of another semiconductor module arrangement.

FIG. 3 is a cross-sectional view of a first connection partner connected to a second connection partner by means of a permanent connection.

FIG. 4 schematically illustrates one step of a method according to embodiments of the disclosure.

FIG. 5 is a cross-sectional view of an arrangement according to embodiments of the disclosure.

FIG. 6 is a cross-sectional view of an arrangement according to further embodiments of the disclosure.

### DETAILED DESCRIPTION

In the following detailed description, reference is made to the accompanying drawings. The drawings show specific examples in which the invention may be practiced. It is to be understood that the features and principles described with respect to the various examples may be combined with each other, unless specifically noted otherwise. In the description as well as in the claims, designations of certain elements as “first element”, “second element”, “third element” etc. are not to be understood as enumerative. Instead, such designations serve solely to address different “elements”. That is, e.g., the existence of a “third element” does not necessarily require the existence of a “first element” and a “second element”. An electrical line or electrical connection as described herein may be a single electrically conductive element, or include at least two individual electrically conductive elements connected in series and/or parallel. Electrical lines and electrical connections may include metal and/or semiconductor material, and may be permanently electrically conductive (i.e., non-switchable). A semiconductor body as described herein may be made from (doped) semiconductor material and may be a semiconductor chip or be included in a semiconductor chip. A semiconductor body has electrically connectable pads and includes at least one semiconductor element with electrodes.

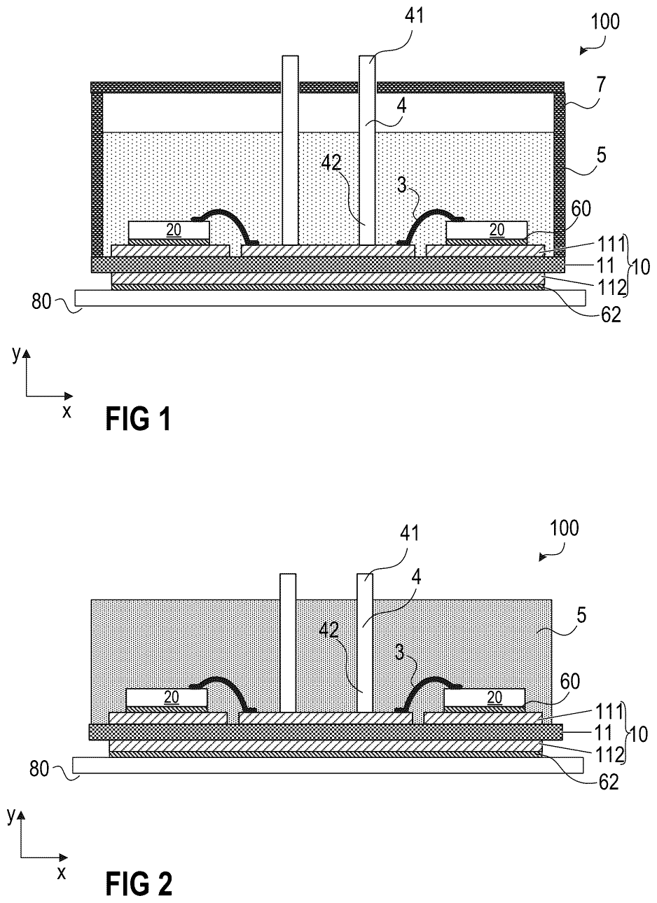

Referring to FIG. 1, a cross-sectional view of a conventional semiconductor module arrangement 100 is illustrated. The semiconductor module arrangement 100 includes a housing 7 and a substrate 10. The substrate 10 includes a dielectric insulation layer 11, a (structured) first metallization layer 111 attached to the dielectric insulation layer 11, and a (structured) second metallization layer 112 attached to the dielectric insulation layer 11. The dielectric insulation layer 11 is disposed between the first and second metallization layers 111, 112.

Each of the first and second metallization layers 111, 112 may consist of or include one of the following materials: copper; a copper alloy; aluminum; an aluminum alloy; any other metal or alloy that remains solid during the operation of the semiconductor module arrangement. The substrate 10 may be a ceramic substrate, that is, a substrate in which the dielectric insulation layer 11 is a ceramic, e.g., a thin ceramic layer. The ceramic may consist of or include one of the following materials: aluminum oxide; aluminum nitride; zirconium oxide; silicon nitride; boron nitride; or any other dielectric ceramic. Alternatively, the dielectric insulation layer 11 may consist of an organic compound and include one or more of the following materials: Al₂O₃, AlN, ZrO₂, SiC, BeO, BN, or Si₃N₄. For instance, the substrate 10 may, e.g., be a Direct Copper Bonding (DCB) substrate, a Direct Aluminum Bonding (DAB) substrate, or an Active Metal Brazing (AMB) substrate. Further, the substrate 10 may be an Insulated Metal Substrate (IMS). An Insulated Metal Substrate generally comprises a dielectric insulation layer 11 comprising (filled) materials such as epoxy resin or polyimide, for example. The material of the dielectric insulation layer 11 may be filled with ceramic particles, for example. Such particles may comprise, e.g., SiO₂, Al₂O₃, AlN, SiN or BN and may have a diameter of between about 1 μm and about 50 μm.

The substrate 10 is arranged in a housing 7. In the example illustrated in FIG. 1, the substrate 10 forms a base surface of the housing 7, while the housing 7 itself solely comprises sidewalls and, optionally, a top or cover. The substrate 10 is attached to a heat sink 80 by means of a connection layer 62. The connection layer 62 in conventional semiconductor modules 100 may be an electrically insulating adhesive layer, a solder layer, a layer of an electrically conductive adhesive, or a layer of a sintered metal powder, e.g., a sintered silver (Ag) powder, for example.

One or more semiconductor bodies 20 may be arranged on the at least one substrate 10. Each of the semiconductor bodies 20 arranged on the at least one substrate 10 may include a diode, an IGBT (Insulated-Gate Bipolar Transistor), a MOSFET (Metal-Oxide-Semiconductor Field-Effect Transistor), a JFET (Junction Field-Effect Transistor), a HEMT (High-Electron-Mobility Transistor), or any other suitable semiconductor element.

The one or more semiconductor bodies 20 may form a semiconductor arrangement on the substrate 10. In FIG. 1, only two semiconductor bodies 20 are exemplarily illustrated. The second metallization layer 112 of the substrate 10 in FIG. 1 is a continuous layer. In some semiconductor modules 100, the second metallization layer 112 may be a structured layer. The first metallization layer 111 is a structured layer in the example illustrated in FIG. 1. “Structured layer” in this context means that the respective metallization layer is not a continuous layer, but includes recesses between different sections of the layer. Such recesses are schematically illustrated in FIG. 1. The first metallization layer 111 in this example includes three different sections. Different semiconductor bodies 20 may be mounted to the same or to different sections of the first metallization layer 111. Different sections of the first metallization layer 111 may have no electrical connection or may be electrically connected to one or more other sections using electrical connections 3 such as, e.g., bonding wires. Semiconductor bodies 20 may be electrically connected to each other or to the first metallization layer 111 using electrical connections 3, for example. Electrical connections 3, instead of bonding wires, may also include bonding ribbons, connection plates or conductor rails, for example, to name just a few examples. The one or more semiconductor bodies 20 may be electrically and mechanically connected to the substrate 10 by an electrically conductive connection layer 60. Such an electrically conductive connection layer 60 may be a solder layer, a layer of an electrically conductive adhesive, or a layer of a sintered metal powder, e.g., a sintered silver (Ag) powder, for example.

The semiconductor module arrangement 100 illustrated in FIG. 1 further includes terminal elements 4. The terminal elements 4 provide an electrical connection between the inside and the outside of the housing 7. The terminal elements 4 may be electrically connected to the first metallization layer 111 with a second end 42, while a first end 41 of the terminal elements 4 protrudes out of the housing 7. The terminal elements 4 may be electrically contacted from the outside at their first end 41.

Arranging the terminal elements 4 centrally on the substrate 10 is only an example. According to other examples, terminal elements 4 may be arranged closer to or adjacent to the sidewalls of the housing 7. The second end 42 of a terminal element 4 may be electrically and mechanically connected to the substrate 10 by means of an electrically conductive connection layer (not specifically illustrated in FIG. 1). Such an electrically conductive connection layer may be a solder layer, a layer of an electrically conductive adhesive, or a layer of a sintered metal powder, e.g., a sintered silver (Ag) powder, for example. Alternatively, the terminal elements 4 may also be coupled to the substrate by means of ultrasonic welding.

The semiconductor module arrangement 100 may further include an encapsulant 5. The encapsulant 5 may consist of or include a cured silicone gel or may be a rigid molding compound, for example. The encapsulant 5 may at least partly fill the interior of the housing 7, thereby covering the components and electrical connections that are arranged on the substrate 10. The terminal elements 4 may be partly embedded in the encapsulant 5. At least their first ends 41, however, are not covered by the encapsulant 5 and protrude from the encapsulant 5 through the housing 7 to the outside of the housing 7. The encapsulant 5 is configured to protect the components and electrical connections of the power semiconductor module 100, in particular the components arranged inside the housing 7, from certain environmental conditions and mechanical damage. The encapsulant 5 is further configured to electrically insulate areas with different potentials (e.g., different sections of the first metallization layer 111) from each other.

The second metallization layer 112 of the substrate 10 is generally not required for the overall function of the semiconductor module 100. That is, the second metallization layer 112 generally does not conduct any currents during operation of the semiconductor module 100. Therefore, it is generally possible that the second metallization layer 112 be omitted altogether. The second metallization layer 112, however, may be required in certain cases in order to be able to directly attach the substrate 10 to a heat sink 80, e.g., by means of conventional sinter pastes or sinter preforms. Heat that is generated during operation of the semiconductor module arrangement 100 is transferred through the substrate 10 and the connection layer 62 to the heat sink 80.

Now referring to FIG. 2, if, for example, the encapsulant 5 is a rigid molding compound, the housing 7 can also be omitted. In this case, the encapsulant 5 is able to sufficiently protect the substrate 10 and any components mounted thereon from mechanical damage.

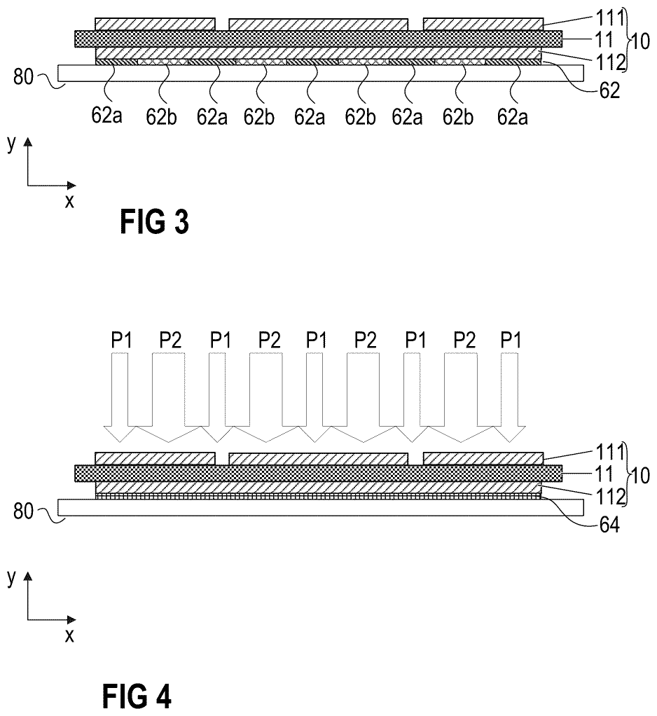

Now referring to FIG. 3, a cross-sectional view of a substrate 10 connected to a heat sink 80 by means of a connection layer 62 is schematically illustrated. The connection layer 62 may be a sintered layer for example. A sintered layer may comprise a sintered metal powder, e.g., a sintered silver (Ag) powder, for example. At least some semiconductor bodies 20 of the semiconductor module arrangement (semiconductor bodies 20 not specifically illustrated in FIG. 3) perform a plurality of switching operations during the operation of the semiconductor module arrangement 100. When performing many switching operations within a short period of time, for example, the semiconductor bodies 20 generate heat. Heat that is generated during the operation of the semiconductor module arrangement 100 is mostly dissipated from the semiconductor bodies 20 to the substrate 10 and further through the connection layer 62 to the heat sink 80.

A sintered connection layer 62 deforms when heated. Usually, some sections of the substrate 10 are heated more than others during operation of the semiconductor module arrangement 100. For example, those regions of a substrate 10 arranged directly below semiconductor bodies 20 may be heated more than other regions of the substrate 10. The temperature distribution is generally dependent on a duration of a current flow through the semiconductor bodies 20. Due to the uneven heating of the substrate 10, the sintered connection layer 62 may also heat unevenly. As the temperatures in some sections of the substrate 10, e.g., below the semiconductor bodies 20, are higher than the temperatures in other sections, the connection layer 62 expands unevenly. In particular, the connection layer 62 expands more in areas arranged below the sections of the substrate 10 that are heated more than in areas below the sections of the substrate 10 that are heated less. Over the lifetime of the semiconductor module arrangement 100, the semiconductor bodies 20 are heated and subsequently cool down many times. The cyclic heating and cooling of the semiconductor bodies 20 and of the connection layer 62 may result in a mechanical fatigue of the connection layer 62, e.g., a mechanical fatigue originating from the areas below the semiconductor bodies 20.

For this reason, the connection layer 62 illustrated in FIG. 3 comprises first regions 62a and second regions 62b. The first regions 62a each have a first porosity and the second regions 62b each have a second porosity. The first porosity is different from the second porosity. For example, the first porosity may be higher than the second porosity. The porosity of a material generally is a measure of the void (e.g., “empty”) spaces in the material, and is a fraction of the volume of voids over the total volume, between 0 and 1. The porosity may also be given as a percentage between 0 and 100%. The porosity of the first regions 62 a may be, for example about 10% or lower, about 15% or lower, about 20% or lower, or about 40% or lower. The porosity of the second regions 62 b may be more than 10%, more than 20%, more than 40% or more than 50%, for example. In other words, the second regions 62b may be more compacted than the first regions 62a.

A low porosity (high compaction) generally provides a high mechanical strength and a good thermal and electric conductivity. A high porosity (low compaction), on the other hand, results in a low stiffness of the connection layer 62 and, therefore, low mechanical stresses in the structure including the semiconductor body 20, the substrate 10 and the connection layer 62.

A method according to embodiments of the disclosure with which a connection layer having areas of different porosity can be produced in a simple and effective way comprises applying a pre-layer 64 to a first connection partner 10 or to a second connection partner 80, arranging the first connection partner 10 on the second connection partner 80, such that the pre-layer 64 is arranged between the first connection partner 10 and the second connection partner 80, and heating the first connection partner 10, the second connection partner 80, and the pre-layer 64 arranged between the first connection partner 10 and the second connection partner 80. While heating the first connection partner 10, the second connection partner 80, and the pre-layer 64, pressure is exerted on the first connection partner 10, thereby pressing the first connection partner 10 towards the second connection partner 80 and forming a permanent connection layer 62 between the first connection partner 10 and the second connection partner 80. Exerting pressure on the first connection partner 10 comprises exerting a first pressure P1 on at least one first section of the first connection partner 10, and exerting a second pressure P2 on at least one second section of the first connection partner 10, wherein the second pressure P2 is greater than the first pressure P1. The resulting permanent connection layer 62 in areas arranged below the at least one first section of the first connection partner 10 has a first porosity, and in areas arranged below the at least one second section of the first connection partner 10 has a second porosity, wherein the second porosity is lower than the first porosity.

FIG. 4 schematically illustrates one step of a method according to embodiments of the disclosure. In particular, FIG. 4 schematically illustrates the step of exerting pressure on the first connection partner 10, thereby pressing the first connection partner 10 towards the second connection partner 80 and forming a permanent connection layer 62 between the first connection partner 10 and the second connection partner 80. The first and second pressure P1, P2 exerted on different sections of the first connection partner 10 are indicated by means of arrows having different thicknesses in FIG. 4.

In the examples described herein, the first connection partner is described as a substrate 10 of a semiconductor module arrangement 100, and the second connection partner is described as a heat sink 80. However, this is only one example. The method can be used to form a permanent connection between any kind of connection partners, when a connection layer 62 having areas of different porosities is to be formed between the respective connection partners 10, 80 for any reason. As mentioned above, a connection layer 62 having areas of different porosities may be advantageous if, during the use of the arrangement, the first connection partner 10 is heated unevenly, and this heat is transferred to the second connection partner 80 through the connection layer 62 such that the connection layer 62 is also heated unevenly.

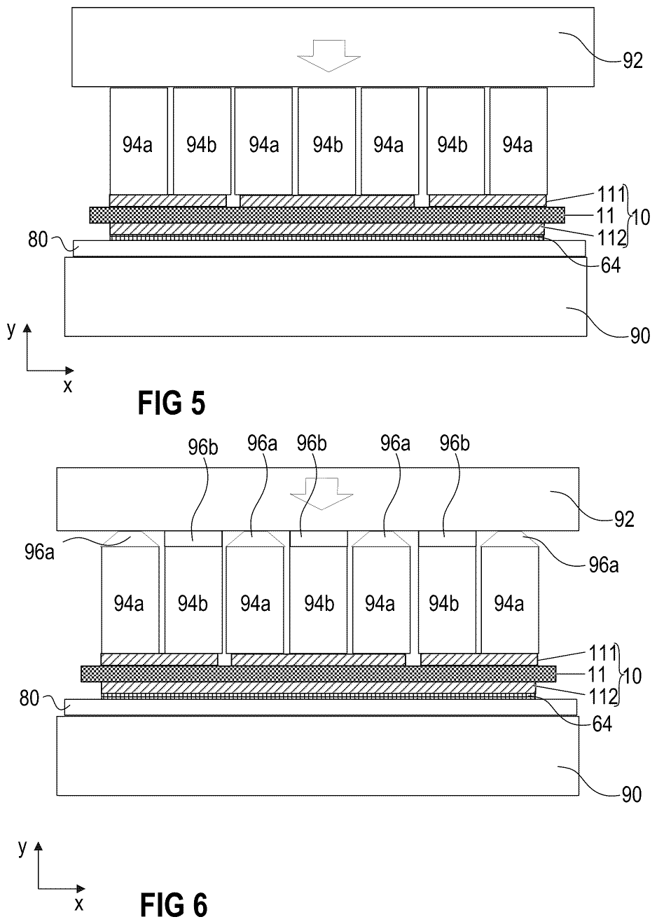

Exerting pressure on the first connection partner 10 may comprise exerting pressure by means of a pressing tool. During the step of exerting pressure on the first connection partner 10, the pressing tool may be in direct contact with the first connection partner 10. If the first connection partner 10 is a substrate of a semiconductor module 100, for example, the pressing tool may be in direct contact with the substrate 10 (e.g., with the first metallization layer 111), as is exemplarily illustrated in FIG. 5. The substrate 10 may be unequipped during the step of exerting pressure thereon, similar to what is shown in FIG. 5. That is, no elements (e.g., semiconductor bodies 20, terminal element 4, electrical connections 3, etc.) may yet be arranged on the substrate 10. This, however, is only an example. It is generally also possible that a substrate 10 be partly or even fully equipped during the step of exerting pressure thereon. However, a housing 7 may not yet be attached to the substrate 10 and the substrate 10 may not yet be covered by an encapsulant 5.

As mentioned above with respect to FIG. 2, a substrate 10 may be molded into a rigid molding compound. Generally speaking, the first connection partner 10 (e.g., substrate 10) may be arranged in a molded package 5, with at least one surface of the first connection partner 10 (e.g., lower surface of second metallization layer 112 which faces away from the dielectric insulation layer 11) facing towards an outside of the molded package 5. That is, at least one surface of the first connection partner 10 may not be covered by the molded package 5 and may be freely accessible. In such cases, during the step of exerting pressure on the first connection partner 10, the pressing tool may be in direct contact with the molded package 5. That is, the pressing tool may exert pressure on the molded package 5, thereby pressing the first connection partner 10 towards the second connection partner 80.

Applying a pre-layer 64 to the first connection partner 10 or to the second connection partner 80 may comprise applying a layer of sinter paste or a sinter preform to the first connection partner 10 or to the second connection partner 80. According to some examples, applying a pre-layer 64 to the first connection partner 10 or to the second connection partner 80 may comprise applying a layer of sinter paste or a sinter preform comprising at least one of copper, and silver to the first connection partner 10 or to the second connection partner 80.

Referring to FIG. 5, an arrangement for forming a permanent connection between two connection partners according to embodiments of the disclosure is schematically illustrated. The arrangement comprises a pressing tool, the pressing tool comprising an upper punch 92, and a plurality of pressure transmission elements 94 attached to the upper punch 92, the plurality of pressure transmission elements 94 comprising at least one pressure transmission element of a first kind 94a and at least one pressure transmission element of a second kind 94b. The upper punch 92 is configured to exert pressure on a first connection partner 10, with the plurality of pressure transmission elements 94 arranged between the upper punch 92 and the first connection partner 10, thereby pressing the first connection partner 10 on a second connection partner 80, with a pre-layer 64 arranged between the first connection partner 10 and the second connection partner 80. Each pressure transmission element of the first kind 94a is configured to transmit a first pressure P1 from the upper punch 92 to one of at least one first section of the first connection partner 10, and each pressure transmission element of the second kind 94b is configured to transmit a second pressure P2 from the upper punch 92 to one of at least one second section of the first connection partner 10, wherein the second pressure P2 is greater than the first pressure P1.

The pressure transmission elements 94 may extend essentially perpendicular to an upper surface of the first connection partner 10, wherein an upper surface of the first connection partner 10 is a surface facing towards the pressing tool while pressure is being exerted on the connection partners 10, 80. A lower surface of each of the pressure transmission elements 94 may be flat, the lower surface of a pressure transmission element 94 being a surface facing away from the upper punch 92.

The upper punch 92 may exert a uniform pressure on the pressure transmission elements 94. However, the pressure transmission elements of the first kind 94a and the pressure transmission elements of the second kind 94b may transmit pressure from the upper punch 92 to the first connection partner 10 with different transmission ratios. In this way, a different amount of pressure can be exerted on different sections of the first connection partner 10. This may be achieved in different ways.

Referring to FIG. 6, according to some embodiments of the disclosure, the pressure transmission elements of the first kind 94a may be attached to the upper punch 92 by means of connection elements of a first kind 96a, and the pressure transmission elements of the second kind 94b may be attached to the upper punch 92 by means of connection elements of a second kind 96b. The connection elements of the first kind 96a transmit pressure from the upper punch 92 to the pressure transmission elements of the first kind 94a at a first transmission ratio, and the connection elements of the second kind 96b transmit pressure from the upper punch 92 to the pressure transmission elements of the second kind 94b at a second transmission ratio that is different from the first transmission ratio.

As is schematically illustrated in FIGS. 5 and 6, the pressure transmission elements of the first kind 94a and the pressure transmission elements of the second kind 94b may have identical cross-sectional areas. That is the pressure transmission elements of the first kind 94a and the pressure transmission elements of the second kind 94b may be identical to each other with respect to their dimensions. The pressure transmission elements of the first kind 94a and the pressure transmission elements of the second kind 94b may also be identical to each other with respect to the material they are made of.

A cross-sectional area of each connection element of the second kind 96b may be constant between the upper punch 92 and the respective pressure transmission element of the second kind 94b. A cross-sectional area of each connection element of the first kind 96a, on the other hand, may increase from a side facing towards the upper punch 92 to an opposite side facing the respective pressure transmission element of the first kind 94a. That is, the pressure that is transferred from the upper punch 92 to the pressure transmission elements of the second kind 94b may be maximal, if the cross-sectional area of the connection elements of the second kind 96b equals the cross-sectional area of the pressure transmission elements of the second kind 94b. The pressure that is transferred from the upper punch 92 to the pressure transmission elements of the first kind 94a, however, is lower, if the cross-sectional area of each connection element of the first kind 96a increases from a side facing towards the upper punch 92 to an opposite side facing the respective pressure transmission element of the first kind 94a. A cross-sectional area of the side of a connection element of the first kind 96a facing the respective pressure transmission element of the first kind 94a may be identical to a cross-sectional area of the respective pressure transmission element of the first kind 94a.

As is further illustrated in FIGS. 5 and 6, the arrangement may further comprise a lower punch 90. The stack formed by the second connection partner 80, the pre-layer 64, and the first connection partner 10 may be arranged on the lower punch 90, with the second connection partner 80 facing towards the lower punch 90. The upper punch 92 is configured to exert pressure on the lower punch 90, with the first connection partner 10, the pre-layer 64, and the second connection partner 80 arranged between the upper punch 92 and the lower punch 90. That is, the lower punch 90 forms a counterpart for the upper punch 92.

During a sintering process, the arrangement may be heated while applying pressure on the connection partners 10, 80 and the pre-layer 64 arranged between the connection partners 10, 80. Therefore, according to some embodiments, the arrangement may further comprise at least one of a first heating unit configured to heat the upper punch 92, and a second heating unit configured to heat the lower punch 90. That is, while exerting pressure by means of the upper punch 92, the upper punch 92 and/or the lower punch 90 may be heated by means of a respective heating unit. Such heat may be transferred from the upper punch 92 and/or the lower punch 90 to the connection partners 10, 80 and the pre-layer 64. The connection partners 10, 80 and the pre-layer 64, however, can alternatively be heated in any other suitable way.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A method, comprising:
applying a pre-layer to a first connection partner or to a second connection partner;
arranging the first connection partner on the second connection partner, such that the pre-layer is arranged between the first connection partner and the second connection partner;
heating the first connection partner, the second connection partner, and the pre-layer arranged between the first connection partner and the second connection partner; and
while heating the first connection partner, the second connection partner, and the pre-layer, exerting pressure on the first connection partner such that the first connection partner is pressed towards the second connection partner and a permanent connection layer is formed between the first connection partner and the second connection partner,
wherein exerting pressure on the first connection partner comprises exerting a first pressure on at least one first section of the first connection partner and exerting a second pressure on at least one second section of the first connection partner, the second pressure being greater than the first pressure,
wherein the permanent connection layer has a first porosity in areas arranged below the at least one first section of the first connection partner and a second porosity in areas arranged below the at least one second section of the first connection partner,
wherein the second porosity is lower than the first porosity.

2. The method of claim 1, wherein exerting pressure on the first connection partner comprises exerting pressure by a pressing tool.

3. The method of claim 2, wherein during the exerting of the pressure on the first connection partner, the pressing tool is in direct contact with the first connection partner.

4. The method of claim 2, wherein the first connection partner is arranged in a molded package, with at least one surface of the first connection partner facing towards an outside of the molded package, and wherein the exerting of the pressure on the first connection partner, the pressing tool is in direct contact with the molded package.

5. The method of claim 1, wherein applying the pre-layer to the first connection partner or to the second connection partner comprises applying a layer of sinter paste or a sinter preform to the first connection partner or to the second connection partner.

6. The method of claim 1, wherein applying the pre-layer to the first connection partner or to the second connection partner comprises applying a layer of sinter paste or a sinter preform comprising at least one of copper and silver to the first connection partner or to the second connection partner.

7. An arrangement for forming a permanent connection between two connection partners, the arrangement comprising:
a pressing tool,
wherein the pressing tool comprises:
an upper punch; and
a plurality of pressure transmission elements attached to the upper punch, the plurality of pressure transmission elements comprising at least one pressure transmission element of a first kind and at least one pressure transmission element of a second kind,
wherein the upper punch is configured to exert pressure on a first connection partner, with the plurality of pressure transmission elements arranged between the upper punch and the first connection partner, such that the first connection partner is pressed on a second connection partner, with a pre-layer arranged between the first connection partner and the second connection partner,
wherein each pressure transmission element of the first kind is configured to transmit a first pressure from the upper punch to one of at least one first section of the first connection partner,
wherein each pressure transmission element of the second kind is configured to transmit a second pressure from the upper punch to one of at least one second section of the first connection partner,
wherein the second pressure is greater than the first pressure.

8. The arrangement of claim 7, wherein:
each pressure transmission element of the first kind is attached to the upper punch by a plurality of connection elements of a first kind;
each pressure transmission element of the second kind is attached to the upper punch by a plurality of connection elements of a second kind;
the connection elements of the first kind are configured to transmit pressure from the upper punch to the pressure transmission elements of the first kind at a first transmission ratio; and
the connection elements of the second kind are configured to transmit pressure from the upper punch to the pressure transmission elements of the second kind at a second transmission ratio that is different from the first transmission ratio.

9. The arrangement of claim 8, wherein the pressure transmission elements of the first kind and the pressure transmission elements of the second kind have identical cross-sectional areas.

10. The arrangement of claim 9, wherein:
a cross-sectional area of each connection element of the second kind is constant between the upper punch and the respective pressure transmission element of the second kind; and
a cross-sectional area of each connection element of the first kind increases from a side facing towards the upper punch to an opposite side facing the respective pressure transmission element of the first kind.

11. The arrangement of claim 7, further comprising:
a lower punch,
wherein the upper punch is configured to exert pressure on the lower punch, with the first connection partner, the pre-layer and the second connection partner arranged between the upper punch and the lower punch.

12. The arrangement of claim 11, further comprising:
a first heating unit configured to heat the upper punch; and
a second heating unit configured to heat the lower punch.

13. The arrangement of claim 7, further comprising:
a heating unit configured to heat the upper punch.
